(19) United States
(12) Patent Application Publication
(10) Pub. No.: US 2025/0311553 A1
(43) Pub. Date: Oct. 2, 2025

(54) DISPLAY PANEL AND DISPLAY DEVICE

(71) Applicants: Hefei Visionox Technology Co., Ltd., Hefei (CN); Visionox Technology Inc., Kunshan (CN)

(72) Inventors: Liping XU, Hefei (CN); Cheng-Yi LIN, Hefei (CN); Po Kun SU, Hefei (CN); Ye XIANG, Hefei (CN); Yuting FU, Hefei (CN); Xiujian ZHU, Hefei (CN)

(73) Assignees: Hefei Visionox Technology Co., Ltd., Hefei (CN); Visionox Technology Inc., Kunshan (CN)

(21) Appl. No.: 18/953,002

(22) Filed: Nov. 19, 2024

Related U.S. Application Data
(63) Continuation of application No. PCT/CN2024/116306, filed on Sep. 2, 2024.

(30) Foreign Application Priority Data
Mar. 27, 2024 (CN) 202410364382.X

(51) Int. Cl. H10K 59/122; H10K 59/80

(52) U.S. Cl. CPC H10K 59/122; H10K 59/873

(57) ABSTRACT

Disclosed are a display panel and a display device, the display panel includes a substrate and an isolation structure, a first encapsulation layer, and a plurality of light-emitting units located on the substrate. The isolation structure includes a plurality of isolation openings respectively defining the plurality of light-emitting units, the first encapsulation layer covers the plurality of isolation openings and the plurality of light-emitting units. A densification of the first encapsulation layer gradually decreases from one side, facing the substrate, of the first encapsulation layer to one side, away from the substrate, of the first encapsulation layer. This solution may improve a flatness of an etched surface of the first encapsulation layer, so that the first encapsulation layer can be more effectively protected in a preparation process of the display panel.

### CROSS-REFERENCE TO RELATED APPLICATIONS

This application is a continuation of International Application No. PCT/CN2024/116306 filed on Sep. 2, 2024, which claims priority to Chinese patent application No. 202410364382.X, filed on Mar. 27, 2024. Both applications are incorporated herein by reference in their entireties.

### TECHNICAL FIELD

The present disclosure relates to the field of display technologies, and in particular, to a display panel and a display device.

### BACKGROUND

An Organic Light-Emitting Diode (OLED) is an organic thin-film electroluminescent unit, which has the advantages of simple preparation process, low cost, low power consumption, high brightness, wide viewing angle, high contrast, flexible display and the like, which is greatly concerned by people and is widely used in electronic display products.

However, current electronic display products are limited to a design of its own structure, and it is difficult to further improve a display effect of a display panel.

### SUMMARY

A first aspect of the present disclosure provides a display panel, which includes a substrate, an isolation structure located on the substrate, a first encapsulation layer and a plurality of light-emitting units. Where the isolation structure includes a plurality of isolation openings respectively defining the plurality of light-emitting units, and the first encapsulation layer covers the plurality of isolation openings and the plurality of light-emitting units. A densification of the first encapsulation layer gradually decreases from one side, facing the substrate, of the first encapsulation layer to one side, away from the substrate, of the first encapsulation layer.

In the above solution, by controlling a distribution of the densification of the first encapsulation layer, a relatively inclined surface may be formed at a side surface of the first encapsulation layer, so as to deposit a protection layer in a subsequent process; in addition, the solution may further improve a flatness of an etched surface of the first encapsulation layer, so that the first encapsulation layer can be more effectively protected in a preparation process of the display panel.

In a specific embodiment of the first aspect of the present disclosure, the first encapsulation layer includes a plurality of encapsulation units respectively corresponding to the plurality of light-emitting units.

Optionally, the first encapsulation layer is an inorganic film layer.

Optionally, an edge of an encapsulation unit of the plurality of encapsulation units extends to a side, facing away from the substrate, of the isolation structure, and a portion of the encapsulation unit located on a side, facing away from the substrate, of the isolation structure is spaced apart from the isolation structure to form a suspending portion.

Optionally, the plurality of light-emitting units are in one-to-one correspondence with the plurality of encapsulation units.

In a specific embodiment of the first aspect of the present disclosure, each encapsulation unit of the plurality of encapsulation units includes a first main surface facing the substrate and/or the isolation structure, a second main surface facing away from the substrate and/or the isolation structure, and a side surface connecting the first main surface and the second main surface, and a side surface of the encapsulation unit is a smooth surface.

In a specific embodiment of the first aspect of the present disclosure, the side surface of the encapsulation unit is a plane, and a plane where the side surface of the encapsulation unit is located intersects and is not perpendicular to a plane where the substrate is located.

In a specific embodiment of the first aspect of the present disclosure, the display panel further includes a pixel defining layer located between the substrate and the isolation structure, the pixel defining layer defines a plurality of pixel openings, the plurality of pixel openings are arranged correspondingly to the plurality of isolation openings; an orthographic projection, on the substrate, of each pixel opening of the plurality of pixel openings is located within an orthographic projection, on the substrate, of each isolation opening of the plurality of isolation openings that corresponding to the pixel opening; and a light-emitting functional layer and a second electrode fill the pixel opening and extend to a surface, facing away from the substrate, of the pixel defining layer.

Optionally, the pixel defining layer may be an inorganic film layer.

In a specific embodiment of the first aspect of the present disclosure, a densification of the pixel defining layer gradually decreases from one side, facing the substrate, of the pixel defining layer to one side, away from the substrate, of the pixel defining layer. In this way, a flatness of a side surface of the pixel opening may be improved to ensure a continuity of the second electrode at the side surface.

Optionally, a second side surface of the pixel defining layer is a smooth surface.

Optionally, a second side surface of the pixel defining layer is a plane, and a plane where the second side surface of the pixel defining layer is located intersects and is not perpendicular to a plane where the substrate is located.

In a specific embodiment of the first aspect of the present disclosure, the isolation structure includes a body portion and a roof portion located on a side, facing away from the substrate, of the body portion; an orthographic projection, on the substrate, of the body portion is located within an orthographic projection, on the substrate, of the roof portion; and an edge of the orthographic projection, on the substrate, of the roof portion is an edge of an orthographic projection, on the substrate, of the isolation structure.

In a specific embodiment of the first aspect of the present disclosure, each light-emitting unit of the plurality of light-emitting unit includes a first electrode, a light-emitting functional layer, and a second electrode sequentially stacked on the substrate, and the light-emitting functional layer and the second electrode of the each light-emitting unit are located in isolation opening, corresponding to the each light-emitting unit, of the plurality of isolation openings.

In a specific implementation of the first aspect of the present disclosure, the display panel further includes a pixel defining layer located between the substrate and the isolation structure, the pixel defining layer defines a plurality of pixel openings, the plurality of pixel openings are arranged correspondingly to the plurality of isolation openings.

Optionally, the light-emitting functional layer and the second electrode fill the pixel opening and extend to a surface, facing away from the substrate, of the pixel defining layer.

Optionally, the body portion is a conductive structure, and the second electrode of the light-emitting unit is electrically connected to the body portion.

In a specific implementation of the first aspect of the present disclosure, the isolation structure may further include an auxiliary body portion, and the auxiliary body portion is located between the body portion and the pixel defining layer. An orthographic projection, on the substrate, of the auxiliary body portion is located within an orthographic projection, on the substrate, of the roof portion, and an orthographic projection, on the substrate, of the body portion is located within an orthographic projection, on the substrate, of the auxiliary body portion.

Optionally, the auxiliary body portion is a conductive structure, and the second electrode of the light-emitting unit is electrically connected to the auxiliary body portion.

Optionally, the display panel further includes a second encapsulation layer and a third encapsulation layer covering the first encapsulation layer, the isolation structure, and a light-transmitting shielding layer, and the second encapsulation layer is located between the first encapsulation layer and the third encapsulation layer.

Optionally, a second encapsulation layer is an organic layer, and a third encapsulation layer is an inorganic layer.

Optionally, a second encapsulation layer is a planarization layer.

In a specific embodiment of the first aspect of the present disclosure, each encapsulation unit of the plurality of encapsulation units includes a first main surface facing the substrate and/or the isolation structure, a second main surface facing away from the substrate and/or the isolation structure, and a side surface connecting the first main surface and the second main surface, along a direction from the first main surface to the second main surface, the side surface includes a plurality of sub-side surfaces connected in sequence, an included angle between a plane and each sub-side surface of the plurality of sub-side surfaces is not greater than 45 degrees, the plane is determined by a first boundary between the side surface and the first main surface and a second boundary between the side surface and the second main surface, and an orthographic projection, on the substrate, of the second main surface is located within an orthographic projection, on the substrate, of the first main surface.

In a specific embodiment of the first aspect of the present disclosure, a refractive index of the first encapsulation layer gradually decreases from the side, facing the substrate, of the first encapsulation layer to the side, away from the substrate, of the first encapsulation layer.

In a specific embodiment of the first aspect of the present disclosure, an oxygen content of the first encapsulation layer gradually increases from the side, facing the substrate, of the first encapsulation layer to the side, away from the substrate, of the first encapsulation layer.

A second aspect of the present disclosure provides a display panel, which includes a substrate and an isolation structure, a first encapsulation layer, and a plurality of light-emitting units located on the substrate. The isolation structure includes a plurality of isolation openings respectively defining the plurality of light-emitting units, the first encapsulation layer covers the plurality of isolation openings and the plurality of light-emitting units, and includes a plurality of encapsulation units respectively corresponding to the plurality of light-emitting units, and each encapsulation unit of the plurality of encapsulation units includes a first main surface facing the substrate and/or the isolation structure, a second main surface facing away from the substrate and/or the isolation structure, and a side surface connecting the first main surface and the second main surface. Along a direction from the first main surface to the second main surface, the side surface includes a plurality of sub-side surfaces connected in sequence, an included angle between a plane and each sub-side surface of the plurality of sub-side surfaces is not greater than 45 degrees, the plane is determined by a first boundary between the side surface and the first main surface and a second boundary between the side surface and the second main surface, and an orthographic projection, on the substrate, of the second main surface is located within an orthographic projection, on the substrate, of the first main surface.

In a specific embodiment of the second aspect of the present disclosure, a plane where the side surface of the encapsulation unit is located intersects and is not perpendicular to a plane where the substrate is located. Optionally, the encapsulation unit includes a first main surface facing the substrate and/or the isolation structure, a second main surface facing away from the substrate and/or the isolation structure, and a side surface connecting the first main surface and the second main surface, and the side surface is a smooth surface. Optionally, a side surface of the encapsulation unit is a plane, and a plane where the side surface of the encapsulation unit is located intersects and is not perpendicular to the plane where the substrate is located.

In a specific embodiment of the second aspect of the present disclosure, a densification of the first encapsulation layer gradually decreases from one side, facing the substrate, of the first encapsulation layer to one side, away from the substrate, of the first encapsulation layer; or, the first encapsulation layer includes at least two sub-encapsulation layers stacked with each other, and a sub-encapsulation layer of the at least two sub-encapsulation layers having a smaller distance to the substrate has a larger refractive index.

In a specific embodiment of the second aspect of the present disclosure, the encapsulation unit includes a first sub-encapsulation layer, a second sub-encapsulation layer and a third sub-encapsulation layer stacked with each other, the first sub-encapsulation layer, the second sub-encapsulation layer and the third sub-encapsulation layer are sequentially arranged along a direction away from the substrate, and densifications or refractive indexes of the first sub-encapsulation layer, the second sub-encapsulation layer and the third sub-encapsulation layer are gradually decreases.

A third aspect of the present disclosure provides a display panel, which includes a substrate and an isolation structure, a first encapsulation layer, and a plurality of light-emitting units located on the substrate. The isolation structure includes a plurality of isolation openings respectively defining the plurality of light-emitting units, the first encapsulation layer covers the plurality of isolation openings and the plurality of light-emitting units, and includes at least two sub-encapsulation layers stacked with each other, and a sub-encapsulation layer of the at least two sub-encapsulation layers having a smaller distance to the substrate has a larger refractive index.

In the above solution, by controlling refractive indexes of different sub-encapsulation layers, densifications of different sub-encapsulation layers may be adjusted, so that the flatness of the etched surface (the side surface below) of the first encapsulation layer is improved, so that the first encapsulation layer can be more effectively protected in the preparation process of the display panel.

In a specific embodiment of the third aspect of the present disclosure, the sub-encapsulation layer of the at least two sub-encapsulation layers having a smaller distance to the substrate has a larger densification.

In a specific embodiment of the third aspect of the present disclosure, the sub-encapsulation layer of the at least two sub-encapsulation layers having a smaller distance to the substrate have a smaller oxygen content.

In a specific implementation of the third aspect of the present disclosure, the first encapsulation layer includes a plurality of encapsulation units respectively corresponding to the plurality of light-emitting units.

In a specific implementation of the third aspect of the present disclosure, the first encapsulation layer is an inorganic film layer.

In a specific implementation of the third aspect of the present disclosure, an edge of an encapsulation unit of the plurality of encapsulation units extends to a side, facing away from the substrate, of the isolation structure, and a portion of the encapsulation unit located on a side, facing away from the substrate, of the isolation structure is spaced apart from the isolation structure to form a suspending portion.

In a specific implementation of the third aspect of the present disclosure, the isolation structure includes a body portion and a roof portion located on a side, facing away from the substrate, of the body portion, an orthographic projection, on the substrate, of the body portion is located within an orthographic projection, on the substrate, of the roof portion, and an edge of the orthographic projection, on the substrate, of the roof portion is an edge of an orthographic projection, on the substrate, of the isolation structure.

In a specific implementation of the third aspect of the present disclosure, each light-emitting unit of the plurality of light-emitting unit includes a first electrode, a light-emitting functional layer and a second electrode sequentially stacked on the substrate, and the light-emitting functional layer and the second electrode of the each light-emitting unit are located in an isolation opening, corresponding to the each light-emitting unit, of the plurality of isolation openings.

In a specific embodiment of the third aspect of the present disclosure, the display panel may further include a pixel defining layer located between the substrate and the isolation structure, the pixel defining layer defines a plurality of pixel openings, the plurality of pixel openings are arranged correspondingly to the plurality of isolation openings, respectively, an orthographic projection, on the substrate, of each pixel opening of the plurality of pixel openings is located within an orthographic projection, on the substrate, of the isolation opening corresponding to the pixel opening, and the light-emitting functional layer and the second electrode fill the pixel opening and extend to a surface, facing away from the substrate, of the pixel defining layer.

In a specific embodiment of the third aspect of the present disclosure, the pixel defining layer is an inorganic film layer

In a specific embodiment of the third aspect of the present disclosure, the pixel defining layer includes at least two sub-defining layers stacked with each other, and a sub-defining layer of the at least two sub-encapsulation layers having a smaller distance to the substrate has a larger refractive index.

In a specific embodiment of the third aspect of the present disclosure, the sub-defining layer of the at least two sub-encapsulation layers having a smaller distance to the substrate has a larger densification.

In a specific embodiment of the third aspect of the present disclosure, a second side surface of the pixel defining layer is a smooth surface.

In a specific embodiment of the third aspect of the present disclosure, the second side surface of the pixel defining layer is a plane, and a plane where the second side surface of the pixel defining layer is located intersects and is not perpendicular to a plane where the substrate is located.

### BRIEF DESCRIPTION OF THE DRAWINGS

FIG. 1 is a schematic diagram of a planar structure of a display panel according to an embodiment of the present disclosure.

FIG. 2 is an enlarged view of a region S1 of the display panel shown in FIG. 1.

FIG. 3 is a cross-sectional view of the display panel shown in FIG. 2 along M-N.

FIG. 4 is an enlarged view of a partial region of the display panel shown in FIG. 3.

FIG. 5 is an enlarged view of a partial region of another display panel according to an embodiment of the present disclosure.

FIG. 6 is a cross-sectional view of a display panel according to an embodiment of the present disclosure.

FIG. 7 is a cross-sectional view of a display panel according to an embodiment of the present disclosure.

FIG. 8A to FIG. 8D are process diagrams of a preparing method for forming the display panel shown in FIG. 6 according to an embodiment of the present disclosure.

FIG. 9 is a schematic diagram of a positional relationship between a partial film layer of a display panel and an evaporation source during evaporation according to an embodiment of the present disclosure.

FIG. 10 is a cross-sectional view of a partial region of a display panel according to an embodiment of the present disclosure.

### DETAILED DESCRIPTIONS OF THE EMBODIMENTS

The technical solutions in the embodiments of the present specification will be clearly and completely described below with reference to the accompanying drawings in the embodiments of the present specification, and obviously, the described embodiments are only a part but not all of the embodiments of the present specification. All other embodiments obtained by a person of ordinary skill in the art based on the embodiments in the present specification without creative efforts shall fall within the protection scope of the present specification.

In display products, some functional film layers in light-emitting units are formed by evaporation, and there are several different types of functional film layers in each light-emitting unit, and some functional film layers (for example, light-emitting layers) in the light-emitting unit emitting different rays of light are made of different materials, and therefore, when these functional film layers are evaporated by a mask plate (for example, a fine mask plate), an alignment operation needs to be performed multiple times, in order to ensure a position offset problem caused by an alignment precision error, enough space (and a safety margin related to alignment error) needs to be reserved between different light-emitting units to ensure that a position of an actual light-emitting region and a design position (a design area) of the light-emitting units has a certain overlap rate, which is equivalent to compressing of a design area of a light-emitting region of the light-emitting units, which not only makes a light-emitting area of the light-emitting units is limited, but also makes an arrangement density of the light-emitting units cannot be further increased, so that a PPI (pixel density) of a display panel is difficult to further improve.

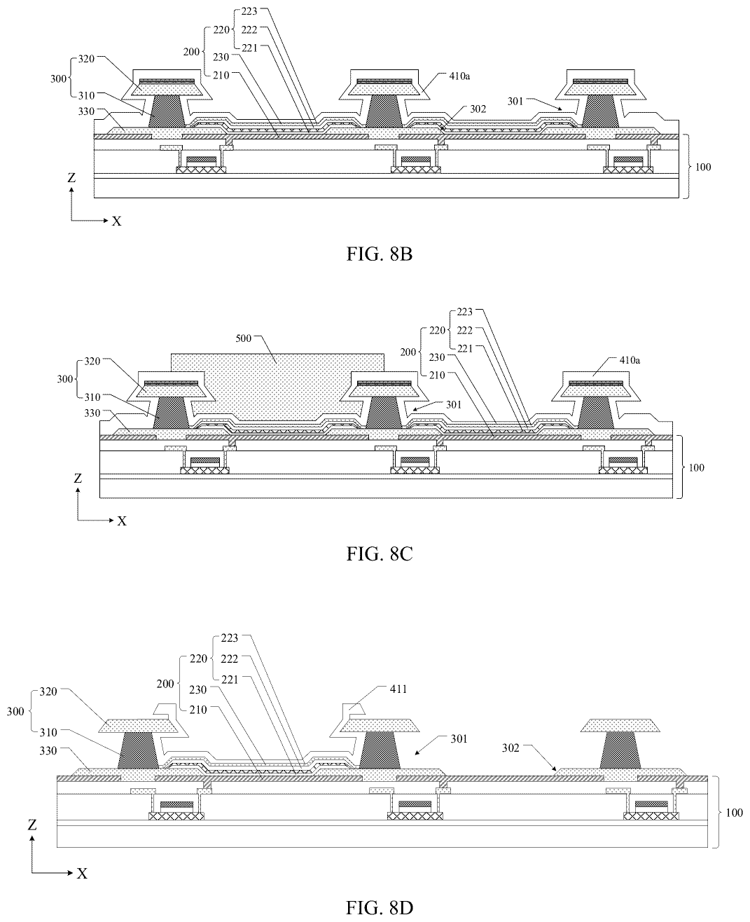

In the present disclosure, the isolation structure is arranged at gaps of the light-emitting units to partition functional film layers of adjacent light-emitting units, so that in an evaporation process of the functional film layers, only an entire side of the display panel needs to be evaporated, without having to prepare a functional film layer of the each light-emitting unit individually with an aid of a mask plate, and this process does not need to consider an alignment precision problem during evaporation, so that the gaps of the light-emitting units can be designed to be smaller in size, so as to increase PPI (a principle thereof can refer to related descriptions in the embodiments related to FIG. 8A to FIG. 8D).

It should be noted that, when the light-emitting units are prepared through the isolation structure, because the light-emitting units are prepared in batches according to different light-emitting colors, after a preparation of previous batch of light-emitting units is finished, a encapsulation structure (a first encapsulation layer as follows) is formed thereon for protection, so as to reduce damages to the previous batch of light-emitting units during a preparation of a next batch of light-emitting units, and correspondingly, the encapsulation structure is also formed several times, and an encapsulation effect of the encapsulation structure directly affects a preparation yield of the light-emitting units. In a forming process of the encapsulation structure, when preparing the next batch of light-emitting units, partial of the film layers (for example, a second electrode described below) will cover the previous batch of light-emitting units and the encapsulation structure (an encapsulation units as follows) thereon to protect the encapsulation structure, and if a flatness of a surface of the encapsulation structure is not high, a quality of the film layers becomes poor and the encapsulation structure thereunder cannot be effectively protected, thereby causing the encapsulation structure to be damaged in a subsequent preparation process such as an etching process, or even causing poor encapsulation of the display panel.

Some embodiments of the present disclosure provide a display panel to solve at least the above technical problems. The display panel includes a substrate, and an isolation structure, a first encapsulation layer, and a plurality of light-emitting units located on the substrate. The isolation structure includes a plurality of isolation openings respectively defining the plurality of light-emitting units, and the first encapsulation layer covers the plurality of isolation openings and the plurality of light-emitting units. A densification of the first encapsulation layer gradually decreases from one side, facing the substrate, of the first encapsulation layer to one side, away from the substrate, of the first encapsulation layer. In this way, by controlling a distribution of the densification of the first encapsulation layer, a relatively inclined surface may be formed at a side surface of the first encapsulation layer, so as to deposit a protection layer in a subsequent process; in addition, the solution may further improve a flatness of an etched surface of the first encapsulation layer, so that a film-forming quality of a protective layer covering the first encapsulation layer may be improved in a preparation process of the display panel, so that the first encapsulation layer can be more effectively protected in the preparation process of the display panel.

Patent PCT/CN2023/134518, CN116583155B, 202310759370.2, 202311117143.6, 202310771071.0, 202310771124.9,, 202311499823.9, 202310771124.9, 202311451935.7, 202311124845.7 describes related content of the isolation structure for reference.

In embodiments of the present disclosure, the densification of a film layer may be an internal molecule or atomic compactness of a corresponding preparation material. The densification is an important performance indicator of a material, and directly affects mechanical properties, thermal properties, electrical properties, and the like of the material. Generally, the larger the densification, the fewer internal voids and defects of the film layer made of the material, and the more compact of a bonding between atoms or molecules, so that a tensile, compression-resistant, anti-bending and anti-corrosion capabilities of the film layer are enhanced. For a structure with same material, the larger the densification, the fewer internal voids or less low-density materials are included.

It should be noted that the internal molecule or atomic compactness of the film layer may also be reflected on a refractive index of the film layer, that is, the more compact of the molecules or atoms, the larger the refractive index of the film layer. In embodiments of the present disclosure, the refractive index of the film layer may be measured by a device such as an ellipsometer. For example, a measurement principle of the ellipsometer is roughly as follows: the elliptical polarization method utilizes elliptically polarized light incident on a surface of a sample, and a change of a polarization state (amplitude and phase) of a reflected light is observed to obtain a thickness and refractive index of a film on the surface of the sample.

A measurement step of the ellipsometer are roughly as following steps S1 to S6:

S1, calibrating the ellipsometer: before performing a measurement, the ellipsometer needs to be calibrated first to ensure that it can accurately measure the refractive index of the sample. A calibration method generally includes two steps of zero offset adjustment and scale adjustment.

S2, preparing a sample: placing the sample to be tested on a sample stage of the ellipsometer.

S3, measuring a phase difference: adjusting parameters of the instrument, so that the ellipsometer outputs a minimum signal, where the phase difference of the sample is measured by the ellipsometer, and the phase difference is proportional to the refractive index of the sample.

S4, calculating the refractive index: calculating the refractive index of the sample through a measurement value of the phase difference according to a working principle of the ellipsometer.

S5, averaging multiple measurements: in order to improve an accuracy of a measurement result, multiple measurements are generally required and an average value is taken, where when multiple measurements are performed, it is necessary to note that a stability of the sample needs to be maintained to avoid an interference of external factors.

S6: controlling environmental conditions: temperature and humidity have a certain influence on the refractive index of the sample, so the environmental conditions need to be controlled to keep them stable during the measurement.

A structure of the display panel according to at least one embodiment of the present disclosure will be described in detail below with reference to the accompanying drawings. In addition, in the drawings, a spatial rectangular coordinate system is established by taking the substrate as a reference, so as to more intuitively present a positional relationship of related structures in the display panel, and in the spatial rectangular coordinate system, a X axis and a Y axis are parallel to a plane where the substrate is located, and a Z axis is perpendicular to the plane where the substrate is located.

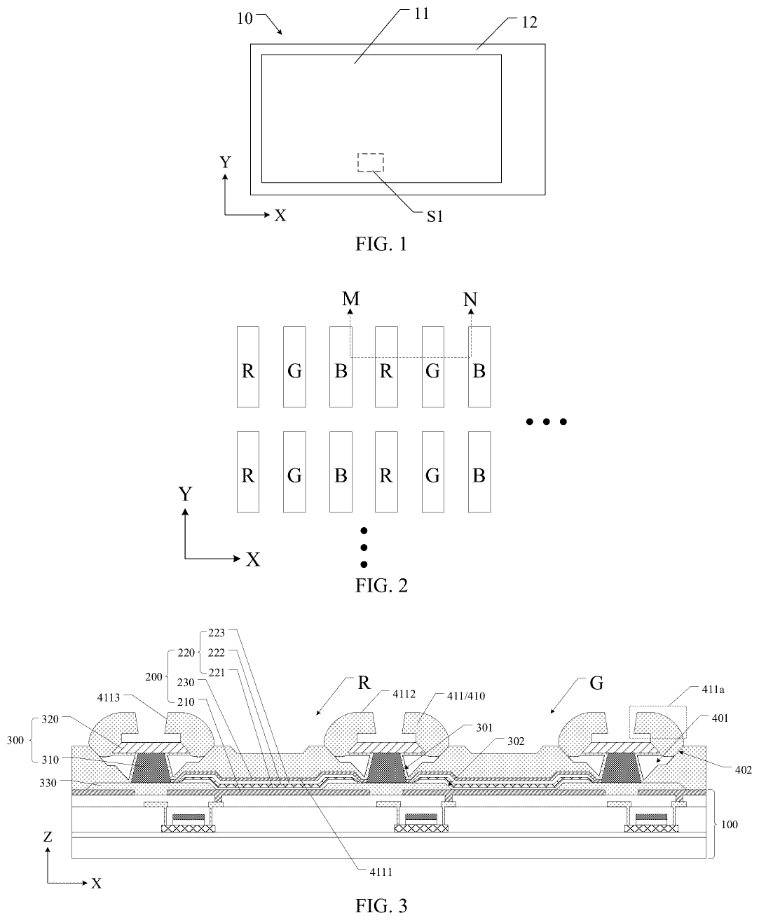

As shown in FIG. 1 to FIG. 4, a planar region of the display panel 10 may be divided into a display region 11 and a border region 12 surrounding the display region 11, and sub-pixels (which may be referred to as sub-pixels, or the like) may be arranged in the display region 11, for example, R, G, and B sub-pixels, and a physical structure of the sub-pixel may be a light-emitting unit, and sub-pixels adjacent to each other and emitting light with different colors constitute a pixel (which may be referred to as a pixel unit, a large pixel, or the like), and an arrangement density of the of the pixel in the display region 11 represents a pixel density PPI. It should be noted that, in some embodiments of the present disclosure, some of the wires in the border region 12 may be arranged in the display region 11, so that the border region 12 may be designed as a one-side border.

A physical structure of the display panel 10 may include a substrate 100 and a display functional layer, an isolation structure 300, and a first encapsulation layer 410 located on the substrate 100, and the display functional layer includes a plurality of light-emitting units 200

The isolation structure 300 is located on the substrate 100 and defines a plurality of isolation openings 301, that is, a planar shape of the isolation structure 300 is presented as a mesh pattern, and the isolation openings 301 are mesh holes of the mesh pattern. In some embodiments of the present disclosure, the isolation openings 301 are in one-to-one correspondence with the light-emitting units 200.

The first encapsulation layer 410 covers the isolation openings 301 and the light-emitting units 200, and a densification of the first encapsulation layer 410 gradually decreases from one side, facing the substrate 100, of the first encapsulation layer 410 to one side, away from the substrate 100, of the first encapsulation layer 410. It should be noted that from the side, facing the substrate 100, of the first encapsulation layer 410 to the side, away from the substrate 100, of the first encapsulation layer 410 may be understood as from a surface of the first encapsulation layer 410 when it is initially deposited to a surface when it is finally formed.

The densification of the first encapsulation layer 410 gradually decreases may be understood as that the densification of the first encapsulation layer presents a continuous variation, at least in a macroscopic view. For example, in one case, the densification of the first encapsulation layer is continuously varied throughout; or, in another case, the first encapsulation layer is divided into a plurality of first intervals and second intervals which are alternately arranged with each other along a thickness direction, a densification in each first interval is continuously varied, a densification in each second interval is constant, and a number of the first intervals and the second intervals is sufficiently large, so that the densification of the first encapsulation layer presents a continuous variation macroscopically.

In the embodiments of the present disclosure, an input power of a device may be controlled in a process (for example, a CVD process) for depositing the first encapsulation layer to control a generation rate of the first encapsulation layer, and when the input power is large, the densification of the first encapsulation layer is high, and correspondingly, when the input power is small, the densification of the first encapsulation layer is low. In this way, a densification variation of each portion of the first encapsulation layer may be controlled by controlling the input power. In an embodiment of the present disclosure, when the densification of the first encapsulation layer is large, a smaller refractive index of the first encapsulation layer may be presented, and accordingly, when the densification of the first encapsulation layer is small, a larger refractive index of the first encapsulation layer may be presented, that is, a refractive index of the first encapsulation layer gradually decreases from one side, facing the isolation structure and/or the substrate, of the first encapsulation layer to one side, away from the isolation structure and/or the substrate, of the first encapsulation layer.

In at least one embodiment of the present disclosure, as shown in FIG. 3, the display panel may further include a first encapsulation layer 410, the first encapsulation layer 410 includes a plurality of encapsulation units 411 in one-to-one correspondence with the isolation openings 301, and the encapsulation units 411 cover the isolation openings 301 corresponding to the encapsulation units 411, and correspondingly, the encapsulation units 411 are in one-to-one correspondence with the light-emitting units 200. A reason why the first encapsulation layer 410 is formed by the plurality of encapsulation units 411 is related to a principle that the light-emitting units 200 are prepared based on the isolation structure 300, for details, refer to related descriptions in the embodiments shown in FIG. 8A to FIG. 8D, and details are not described herein again.

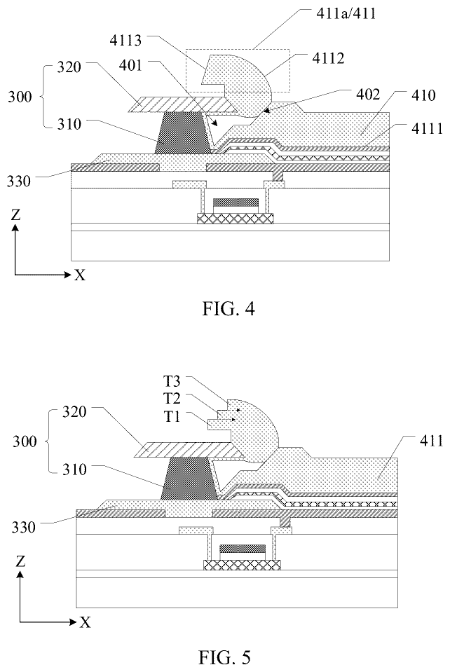

In at least one embodiment of the present disclosure, as shown in FIG. 3 and FIG. 4, at least based on a consideration of improving an encapsulation effect, each encapsulation unit 411 of the encapsulation units 411 may extend to one side, facing away from the substrate 100, of the isolation structure 300, and a principle thereof may refer to related descriptions in the embodiments shown in FIG. 8A to FIG. 8D. In this case, a portion of the encapsulation unit 411 overlapping with an upper surface of the isolation structure 300 (one side, facing away from the substrate, of the roof portion, which will be described below) may form a suspending portion 411a to be spaced apart from the roof portion 320.

In some embodiments of the present disclosure, as shown in FIG. 3 and FIG. 4, the encapsulation unit 411 includes a first main surface 4111 facing the substrate 100 and/or the isolation structure 300, a second main surface 4112 facing away from the substrate 100 and/or the isolation structure 300, and a side surface 4113 connecting the first main surface 4111 and the second main surface 4112, and the side surface 4113 of the encapsulation unit 411 is at least macroscopically presented as a smooth surface. The first main surface 4111 is a lower surface of the encapsulation unit 411, that is, a starting surface of the first encapsulation layer 410 when it is formed, the second main surface 4112 is an upper surface of the encapsulation unit 411, that is, an ending surface of the first encapsulation layer 410 when it is formed, the side surface 4113 of the encapsulation unit 411 is a side surface 4113 of the suspending portion 411a. In a case that the densification of the first encapsulation layer 410 is gradually varied, the side surface 4113 of the encapsulation unit 411 is formed by etching in a preparation process of the encapsulation unit 411, and in an etching process, there is no etching difference mutation at the side surface 4113 of the encapsulation unit 411 due to a densification gradient difference, so that the side surface 4113 obtained by etching is smooth.

In an embodiment of the present disclosure, the “smooth surface” is intended to: in a direction perpendicular to the substrate, a slope of each position on the line intercepted on the surface is continuously varied (there is no mutation, that is, derivable in a mathematical sense).

In at least one embodiment of the present disclosure, as shown in FIG. 3 and FIG. 4, a side surface of the encapsulation unit 411 is a plane, and a plane where a side surface of the encapsulation unit 411 is located intersects and is not perpendicular to a plane where the substrate 100 is located. In this way, a side wall of the encapsulation unit 411 may have a certain gradient, so that in a subsequent process of preparing the light-emitting unit 200 (not covered by the encapsulation unit 411 in subsequent batches), a protective layer (for example, formed on a same layer as a light-emitting functional layer and a second electrode described below) may be conveniently deposited on the side surface.

Some other embodiments of the present disclosure provide a display panel, which includes a substrate and an isolation structure, a first encapsulation layer, and a plurality of light-emitting units located on the substrate. The isolation structure has a plurality of isolation openings that respectively defining the light-emitting units, and the first encapsulation layer covers the isolation openings and the light-emitting units. For structures other than the first encapsulation layer, reference may be made to the related descriptions in the foregoing embodiments, and in this embodiment, the first encapsulation layer may be designed as a multi-layer structure, and a principle of the first encapsulation layer is substantially same as the solution (a densification is gradually varied) mentioned in the foregoing embodiments. The first encapsulation layer may include at least two sub-encapsulation layers stacked with each other, a sub-encapsulation layer of the at least two sub-encapsulation layers having a smaller distance to the substrate has a larger refractive index. For example, as shown in FIG. 5, an encapsulation unit 411 (or the first encapsulation layer 410) includes a first sub-encapsulation layer T1, a second sub-encapsulation layer T2, and a third sub-encapsulation layer T3 stacked with each other, the first sub-encapsulation layer T1, the second sub-encapsulation layer T2, and the third sub-encapsulation layer T3 are sequentially arranged in a direction away from the substrate, and in order to form the encapsulation unit 411 with a sloped side surface in a process of forming the encapsulation unit 411, refractive indexes of the first sub-encapsulation layer T1, the second sub-encapsulation layer T2, and the third sub-encapsulation layer T3 are sequentially decreases (or the densifications are sequentially decreases) by different process conditions. It should be noted that the refractive indexes of the first sub-encapsulation layer T1, the second sub-encapsulation layer T2, and the third sub-encapsulation layer T3 itself may be invariable, or may also be gradually varied, in a latter case, sub-encapsulation layers closer to the substrate have a larger refractive index. It should be noted that, for the sub-encapsulation layer described above, for the sub-encapsulation layers, the larger the refractive index, the larger the densification. In this way, the densifications of different sub-encapsulation layers can be adjusted by controlling the refractive indexes of different sub-encapsulation layers, so that a flatness of an etched surface of the first encapsulation layer 410 is improved, so that the first encapsulation layer 410 can be more effectively protected in a preparation process of the display panel.

In at least one embodiment of the present disclosure, the sub-encapsulation layers having a smaller distance to the substrate have a smaller oxygen content.

In the embodiments of the present disclosure, specific structural designs of the isolation structure, a light-emitting unit, and the like are not limited, and may be designed according to requirements of actual processes. In the following, arrangement manners of these structures are exemplarily described by means of several specific embodiments.

In at least one embodiment of the present disclosure, along a direction from the first main surface to the second main surface, the side surface includes a plurality of sub-side surfaces connected in sequence, an included angle between a plane and each sub-side surface of the plurality of sub-side surfaces is not greater than 45 degrees, the plane is determined by a first boundary between the side surface and the first main surface and a second boundary between the side surface and the second main surface, and an orthographic projection, on the substrate, of the second main surface is located within an orthographic projection, on the substrate, of the first main surface. For example, as shown in FIG. 5, side surfaces of the first sub-encapsulation layer T1, the second sub-encapsulation layer T2, and the third sub-encapsulation layer T3 are respectively corresponding to the sub-side surfaces.

In at least one embodiment of the present disclosure, referring back to FIG. 4, the isolation structure 300 may include a body portion 310 facing the substrate 100 and a roof portion 320 facing away from the substrate 100, and an orthographic projection, on the substrate 100, of the body portion 310 is located within an orthographic projection, on the substrate 100, of the roof portion 320, that is, the isolation structure 300 is integrally presented as a wide top and a narrow bottom, so that the isolation structure 300 is disconnected at an edge of the isolation structure 300 when a portion of the film layers (for example, a light-emitting functional layer described below) of the light-emitting unit 200 is evaporated, so as to reduce a risk of crosstalk of adjacent light-emitting units.

Limited to a fact that the isolation structure 300 is designed with a wide top and a narrow bottom, the first encapsulation layer 410 will form a space 401 on one side of the isolation structure 300. In addition, a parameter such as a thickness of the first encapsulation layer 410 can be used to enable a portion, covering the roof portion 320, of the first encapsulation layer 410 and a portion, covering the light-emitting unit 200, of the first encapsulation layer 410 to be closed (a position of a contact surface 402, which is to be noted, the contact surface 402 is not a dividing interface), so that the space 401 is a closed space 401. In this way, in a process of preparing different types of light-emitting units 200, harmful materials such as corrosive liquid or etching gas will not flow into the closed space 401, so as to avoid the encapsulation unit 411 from being etched and damaged. It should be noted that the contact surface 402 is a virtual interface that only calibrates a closed position.

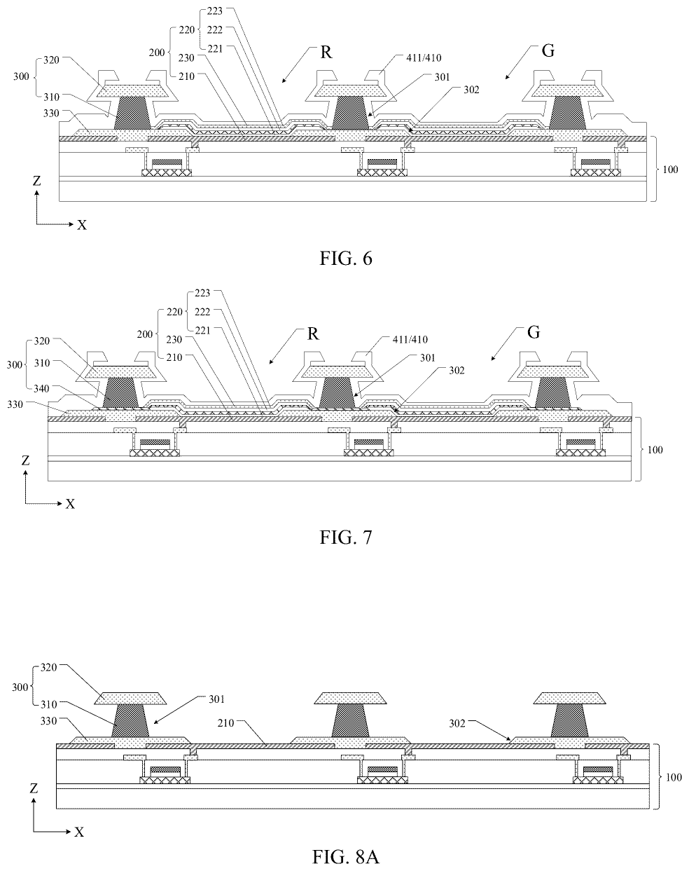

It should be noted that the first encapsulation layer 410 is not limited to forming the closed space shown in FIG. 3, but may be formed into an open space shown in FIG. 6, which may be specifically selected according to requirements of an actual process, and details are not described herein again.

In at least one embodiment of the present disclosure, as shown in FIG. 6, each light-emitting unit 200 includes a first electrode 210, a light-emitting functional layer 220, and a second electrode 230 sequentially stacked on the substrate 100, the light-emitting functional layer 220 and the second electrode 230 of the each light-emitting unit 200 are located in an isolation opening 301, corresponding to the each light-emitting unit 200, of the plurality of isolation openings 301. In a preparation process of the light-emitting functional layer 220, the isolation structure 300 (the roof portion 320 included therein) may limit a diffusion range of an evaporation material, so that an orthographic projection, on the substrate 100, of an edge of the roof portion 320 is located within an orthographic projection, on the substrate 100, of the light-emitting functional layer 220 and the second electrode 230, for details, refer to related descriptions in the embodiments of the preparation method of the display panel, and which are not described herein again.

For example, the light-emitting functional layer may further include a light-emitting layer 222 and a second functional layer 223, and the first functional layer 221, the light-emitting layer 222, and the second functional layer 223 are sequentially stacked on the first electrode 210. The first functional layer 221 may include a hole injection layer, a hole transport layer, an electron blocking layer, and the like. The second functional layer 223 may include an electron injection layer, an electron transport layer, a hole blocking layer, and the like. It should be noted that, due to a fact that a crosstalk of carriers (holes and electrons) is happened mainly between adjacent light-emitting units 200 through the first functional layer 221, an arrangement of the isolation structure 300 needs to make the first functional layers 221 of the light-emitting units 200 electrically disconnected from each other.

For example, in at least one embodiment of the present disclosure, the first electrode may be set as an anode, and the second electrode may be set as a cathode.

The isolation structure 300 may be disconnected at an edge of the roof portion 320 during an evaporation process due to a wide top and a narrow bottom shape of the isolation structure 300, that is, the first functional layer 221 may not be connected to a conductive portion (for example, the body portion 310) of the isolation structure 300, which resulting in a crosstalk between the adjacent light-emitting units 200.

In the embodiments of the present disclosure, the isolation structure is configured to communicate with the second electrode, so as to prevent the isolation structure from being connected to the first electrode, a size of the first electrode may be reduced to be spaced apart from the isolation structure, or an insulating layer may be disposed between the first electrode and the isolation structure.

It should be noted that, after a batch of the light-emitting units 200 and the encapsulation units 411 thereon are prepared, when a next batch of light-emitting units 200 are prepared, a film layer for forming the light-emitting functional layer 220 and the second electrode 230 may cover a surface (including a side surface) of the encapsulation unit 411, and the film layer forms a protective layer. The second electrode 230 needs to consider both an electrical conductivity and a light transmittance, so that the second electrode 230 has a relatively thin thickness, in this way, if a flatness of the side surface of the encapsulation unit 411 is poor, the film layer used to form the second electrode 230 is difficult to have good continuity on the side surface thus have a low film forming quality, in this way, in a process of preparing the encapsulation unit 411 of the next batch, the protective layer is difficult to protect the encapsulation unit 411 that has been prepared in a previous batch, thereby resulting in a risk of poor encapsulation of the display panel.

For example, in at least one embodiment of the present disclosure, as shown in FIG. 6, the display panel may further include a pixel defining layer 330 located between the substrate 100 and the isolation structure 300, the pixel defining layer 330 defines a plurality of pixel openings 302 arranged correspondingly to the plurality of isolation openings 301, respectively; an orthographic projection, on the substrate 100, of each pixel openings 302 of the plurality of pixel openings 302 is located within an orthographic projection, on the substrate 100, of the isolation opening 301 corresponding to the pixel opening 302; and the light-emitting functional layer 220 and the second electrode 230 fill the pixel opening 302 and extend to a surface, facing away from the substrate 100, of the pixel defining layer 330. In each isolation opening 301, the orthographic projection, on the substrate 100, of the pixel opening 302 coincides with a light-emitting region of the light-emitting unit 200, that is, the pixel defining layer 330 defines the light-emitting region of the light-emitting unit 200.

In at least one embodiment of the present disclosure, the pixel defining layer 330 may be an inorganic film layer. An inorganic layer has large densification and strong resistance, so that a design thickness of the display panel can be reduced; in addition, the pixel defining layer 330 with a smaller thickness facilitates a continuity of the second electrode 230.

In the embodiment of the present disclosure, a flatness of a side surface of the pixel opening 302 enclosed by the pixel defining layer 330 may also affect the continuity of the second electrode 230, and therefore, the pixel defining layer 330 may also be designed with reference to the first encapsulation layer mentioned in the foregoing embodiments.

In some embodiments of the present disclosure, a densification of the pixel defining layer 330 gradually decreases from one side, facing the substrate 100, of the pixel defining layer 330 to one side, away from the substrate 100, of the pixel defining layer 33. In this way, the flatness of the side surface of the pixel opening 302 can be improved to ensure the continuity of the second electrode 230 at the side surface.

It should be noted that, for a manner of controlling a distribution of the densification in a preparation process of the pixel defining layer 330, reference may be made to the related description of a preparation manner of the first encapsulation layer in the foregoing embodiments, and details are not described herein again.

In the embodiment of the present disclosure, the pixel defining layer may be presented with a smaller refractive index when the densification of the pixel defining layer is large, and correspondingly, the pixel defining layer may be presented with a larger refractive index when the densification of the pixel defining layer is small, that is, the refractive index of the pixel defining layer gradually decreases from the side, facing the substrate, of the pixel defining layer to the side, away from the substrate, of the pixel defining layer.

In some other embodiments of the present disclosure, the pixel defining layer 330 includes at least two sub-defining layers stacked with each other, and a sub-defining layer of the at least two sub-encapsulation layers having a smaller distance to the substrate 100 has a larger refractive index. In this case, the sub-defining layer having a smaller distance to the substrate 100 has a larger densification. In this way, by controlling refractive indexes of different sub-defining layers, densifications of different sub-defining layers can be adjusted, so that the flatness of the side surface of the pixel opening can be improved to ensure the continuity of the second electrode at the side surface.

In at least one embodiment of the present disclosure, a side surface of the pixel defining layer 330 is a smooth surface. For example, the side surface of the pixel defining layer 330 is a plane, and a plane where the side surface of the pixel defining layer 330 is located intersects and is not perpendicular to a plane where the substrate 100 is located. An arrangement like this may facilitate ensuring continuity of the second electrode 230 at the side surface of the pixel defining layer 330.

In at least one embodiment of the present disclosure, as shown in FIG. 7, the isolation structure 300 may further include an auxiliary body portion 340, the auxiliary body portion 340 is located on one side, facing away from the roof portion 320, of the body portion 310, an orthographic projection, on the substrate 100, of the auxiliary body portion 340 is located within an orthographic projection, on the substrate 100, of the roof portion 320, and an orthographic projection, on the substrate 100, of the body portion 310 is located within an orthographic projection, on the substrate 100, of the auxiliary body portion 340.

For example, the auxiliary body portion 340 is a conductive structure, a portion of a surface, facing away from the substrate 100, of the auxiliary body portion 340, which is not covered by the body portion 310 may be used to make contact with the second electrode 230, and a deposition thickness, on a surface of the auxiliary body portion 340, of the second electrode 230 may be larger compared with a side wall of the body portion 310, so that the auxiliary body portion 340 has a larger contact area and bonding strength with the second electrode 230, thereby reducing an impedance between the second electrode 230 and the isolation structure 300.

For example, the roof portion 320, the body portion 310, and the auxiliary body portion 340 may be made of titanium, aluminum, and molybdenum in sequence, and a corrosion resistance of the titanium, the molybdenum, and the aluminum is sequentially decreases, so that the isolation structure 300 shown in FIG. 7 may be formed.

For example, in some embodiments of the present disclosure, the body portion 310 and the roof portion 320 may be an integrated structure, the isolation structure 300 is a conductive structure, and the second electrode 230 of the light-emitting unit 200 is electrically connected with the body portion 310. The integrated structure may be an independent film layer, and there is no physical interface in the film layer, and the body portion 310 and the roof portion 320 are two portions of the integrated structure. For example, further, along a direction perpendicular to the substrate 100, a shape of a cross-sectional of the roof portion 320 is an inverted trapezoid, and a top edge of the inverted trapezoid faces the substrate 100, that is, the top edge of the inverted trapezoid is located between the substrate 100 and a bottom edge of the inverted trapezoid.

For example, in some other embodiments of the present disclosure, the body portion 310 and the roof portion 320 are two independent film layers, the body portion 310 is a conductive structure, and the second electrode 230 of the light-emitting unit 200 is electrically connected with the body portion. For example, further, along the direction perpendicular to the substrate 100, a shape of a cross-sectional of the body portion 310 is a positive trapezoid, and the roof portion is located at a top edge of the body portion 310. In this case, it may be facilitated for an evaporation material of the second electrode 230 to be deposited on the side wall of the body portion 310 to improve an overlapping yield of the second electrode 230 and the body portion 310.

At least one embodiment of the present disclosure provides a method for preparing a display panel, the method for preparing a display panel includes: providing a substrate; forming an isolation structure and a plurality of light-emitting units on the substrate, where a plurality of isolation openings are formed in the isolation structure, and the plurality of isolation openings defining the plurality of light-emitting units; and forming at least one first film layer on the substrate, where an input power at the time of a generation of the first film layer is gradually decreases, so that a densification of the first film layer gradually decreases in a direction away from the substrate. For a specific structure of the display panel prepared based on the method may be refer to related descriptions in the foregoing embodiments. It should be noted that the first film layer may include at least one of the first encapsulation layer and the pixel defining layer mentioned in the foregoing embodiments.

For example, in the method for preparing a display panel mentioned in at least one embodiment of the present disclosure, the first film layer includes at least two sub-encapsulation layers stacked with each other, and a step of forming the first film layer on the substrate includes: regulating the input power, so that the densification of the at least two sub-encapsulation layers is gradually decreases. For a specific process, refer to related descriptions in the foregoing embodiments.

For example, in the method for preparing a display panel mentioned in at least one embodiment of the present disclosure, the first film layer includes a first encapsulation layer, and the first encapsulation layer is formed on one side, facing away from the substrate, of the isolation structure and covers the isolation openings and the light-emitting units. For example, the first encapsulation layer includes a plurality of encapsulation units respectively corresponding to the light-emitting units. For example, each encapsulation unit of the encapsulation units includes a first main surface facing the substrate and/or the isolation structure, a second main surface facing away from the substrate and/or the isolation structure, and a side surface connecting the first main surface and the second main surface, and the side surface of the encapsulation unit is a smooth surface. For example, the side surface of the encapsulation unit is a plane, and a plane where the side surface of the encapsulation unit is located intersects and is not perpendicular to a plane where the substrate is located. For a specific structure of the first encapsulation layer in the display panel, refer to related descriptions in the foregoing embodiments, and details are not described herein again.

For example, in the method for preparing a display panel mentioned in at least one embodiment of the present disclosure, the first film layer includes a pixel defining layer, the pixel defining layer is located between the substrate and the isolation structure and is formed with a plurality of pixel openings, the pixel openings are arranged correspondingly to the isolation openings, and an orthographic projection, on the substrate, of each pixel opening of the pixel openings is located within an orthographic projection, on the substrate, of the isolation opening corresponding to the pixel opening. For example, a second side surface of the pixel defining layer is a smooth surface. For example, the second side surface of the pixel defining layer is a plane, and a plane where the second side surface of the pixel defining layer is located intersects and is not perpendicular to the plane where the substrate is located. For a specific structure of the pixel defining layer in the display panel, refer to related descriptions in the foregoing embodiments.

It should be noted that, in the embodiments of the present disclosure, in a case that the light-emitting units 200 are classified into a plurality of types emitting light of different colors, the light-emitting units 200 emitting light of different colors are independently fabricated, but a film layer (the evaporation coating layer, such as a light-emitting functional layer and the like) in each of the light-emitting units 200 is evaporated on an entire surface of the display panel during evaporation. For example, the light-emitting units 200 are classified into light-emitting units that emit red light (R), green light (G), and blue light (B) respectively, and the light-emitting units R, G, and B are sequentially prepared in a preparation process; when the light-emitting unit R is prepared, the light-emitting unit R is formed in each of the isolation openings 301, the first encapsulation layer 410 is prepared on the display panel to cover the light-emitting unit G, and then the first encapsulation layer 410 in a portion of the isolation openings 301 (which is used to form the light-emitting units G, B in a final product) and a second electrode and a light-emitting functional layer of the light-emitting unit R are removed to obtain the encapsulation unit 411, and in this process, the first encapsulation layer 410 is used to protect the light-emitting units R in other isolation openings 301, based on which the light-emitting units G and B sequentially prepared to finally form the first encapsulation layer 410 shown in FIG. 8, that is, the first encapsulation layer 410 on the entire display panel is obtained by multiple processes.

It should be noted that, in the embodiments of the present disclosure, a preparation sequence of the three types of light-emitting units R, G and B is not limited, which may be designed according to requirements of an actual process, for example, the preparation process may also be implemented based on an order of the light-emitting units B, G, and R.

The preparation process of the display panel shown in FIG. 8 is described below with reference to FIG. 8A to FIG. 8D, so as to visually display a principle that the isolation structure may increase a pixel arrangement density PPI.

As shown in FIG. 8A, providing a substrate 100, and forming first electrodes 210 arranged in an array on the substrate 100; depositing an insulating material film layer (for example, an inorganic material film layer) on the substrate 100 on which the first electrodes 210 are formed; forming a body portion 310 and a roof portion 320 on the display panel; and performing a patterning process on the insulating material film layer to form a pixel defining layer 330 (a planar shape is a mesh shape), where the pixel defining layer 330 covers gaps of adjacent first electrodes 210, so that the planar shape of the pixel defining layer 330 is a mesh shape.

In an embodiment of the present disclosure, the patterning process may be a photolithography patterning process, for example, may include: coating a photoresist on a structural layer that needs to be patterned, exposing the photoresist by using a mask, developing the photoresist exposed to obtain a photoresist pattern, etching the structural layer by using the photoresist pattern (optionally wet etching or dry etching), and then optionally removing the photoresist pattern. It should be noted that, in a case that a material of the structural layer (for example, a photoresist pattern 500 described below) includes a photoresist, the structural layer may be directly exposed through a mask to form a required pattern.

As shown in FIG. 8B, evaporating a light-emitting functional layer 220 and a second electrode 230 on the substrate 100, so as to form a light-emitting unit 200 in each isolation opening 301 of the isolation structure 300, and the evaporation does not employ a mask in this process, so that an evaporation material will also be deposited on the roof portion 320; and then depositing to form a first encapsulation film layer 410a to cover the light-emitting unit 200. For example, a light-emitting layer in the light-emitting functional layer 220 evaporated may be red-emitting, that is, in this stage, each isolation opening 301 of the isolation structure 300 is formed with the light-emitting unit 200 that emits red light.

As shown in FIG. 8C, forming a photoresist (for example, coating and the like) on the substrate 100 on which the first encapsulation film layer 410a is formed, then performing a patterning process on the photoresist to form a photoresist pattern 500, and the photoresist pattern 500 only covers a portion of the isolation opening 301 of the isolation structure 300.

As shown in FIG. 8D, etching a surface of the display panel by using the photoresist pattern 500 as a mask to remove the first encapsulation film layer 410a, the second electrode 230, and the light-emitting functional layer 220 not covered by the photoresist pattern 500, where a remaining portion of the first encapsulation film layer 410a forms an encapsulation unit 411 shown in FIG. 8; and then removing a residual photoresist pattern 500.

In this process, corrosive liquid (or etching gas) is used to remove the residual photoresist pattern 500, and the corrosive liquid will enter a space at a side wall of the body portion 310 to damage the first encapsulation layer 410.

The steps of FIG. 8A to FIG. 8D are repeated to respectively form the light-emitting unit 200 that emits green light and the light-emitting unit 200 that emits blue light in other isolation openings 301, and a display panel shown in FIG. 8 is formed.

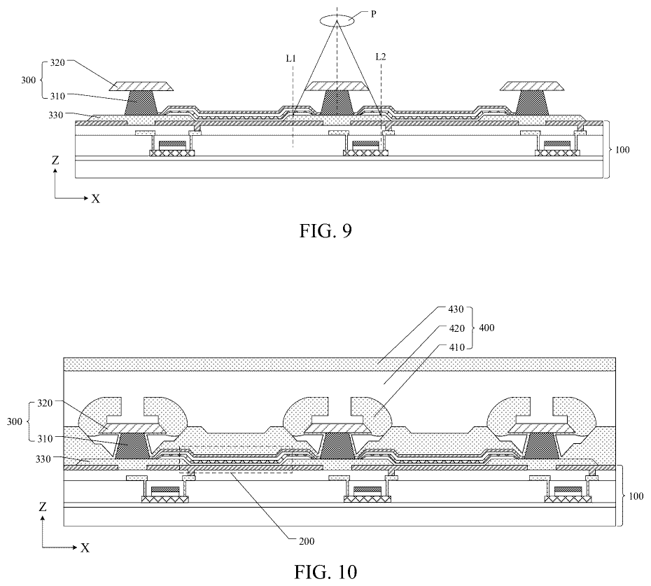

As shown in FIG. 9, when evaporation is performed on the light-emitting functional layer (for example, a first functional layer therein), if an evaporation source P moves to be directly opposite to the isolation structure 300, a corresponding position of a boundary of an evaporation angle on the display panel is a line L1 and a line L2, that is, an area before the line L1 and the line L2 will not evaporated, and an area of one side, facing away from the isolation structure 300, of the line L1 and the line L2 will be evaporated regardless of a position of the evaporation source P. That is, starting from a region of the line L1 or the line L2, the closer to the isolation structure 300, the smaller a thickness of the light-emitting functional layer.

In at least one embodiment of the present disclosure, as shown in FIG. 10, the first encapsulation layer 410 forms a space at one side of the isolation structure 300. In addition, a portion, covering the roof portion 320, of the first encapsulation layer 410 is closed (in contact) with a portion, covering the light-emitting unit 200, of the first encapsulation layer 410, so that the space is a closed space. In this way, in a process of preparing different types of light-emitting units, harmful materials such as corrosive liquid or etching gas will not flow into the closed space.

In at least one embodiment of the present disclosure, as shown in FIG. 10, the display panel further includes a second encapsulation layer 420 and a third encapsulation layer 430 covering the first encapsulation layer 410, the isolation structure, and a light-transmitting shielding layer, and the second encapsulation layer 420 is located between the first encapsulation layer 410 and the third encapsulation layer 430. The first encapsulation layer 410, the second encapsulation layer 420, and the third encapsulation layer 430 constitute an encapsulation layer 400.

In at least one embodiment of the present disclosure, as shown in FIG. 10, the first encapsulation layer 410 and the third encapsulation layer 430 are inorganic layers, and the second encapsulation layer 420 is an organic layer. For example, further, the second encapsulation layer 420 is a planarization layer. The inorganic layer has a high compactness to isolate water and oxygen, and the second encapsulation layer 420 is an organic layer, thereby having a larger thickness to planarize a surface of the display panel.

In at least one embodiment of the present disclosure, as shown in FIG. 10, the substrate 100 may include a substrate and a driving circuit layer located on the substrate, the driving circuit layer includes a plurality of pixel driving circuits located in a display region, and the display functional layer is located on the driving circuit layer. For example, the pixel driving circuit may include a plurality of transistors TFTs, capacitors, and the like, for example, formed in various forms such as 2T1C (that is, two transistors (TFTs) and one capacitor (C)), 3T1C, or 7T1C. The pixel driving circuit is connected with the light-emitting unit 200 to control an on-off state and a luminous brightness of the light-emitting unit 200.

At least one embodiment of the present disclosure provides a display panel, which includes a substrate and an isolation structure, a first encapsulation layer, and a plurality of light-emitting units located on the substrate. The isolation structure includes a plurality of isolation openings respectively defining the plurality of light-emitting units, the first encapsulation layer covers the plurality of isolation openings and the plurality of light-emitting units, and includes a plurality of encapsulation units respectively corresponding to the plurality of light-emitting units, each encapsulation unit of the plurality of encapsulation units includes a first main surface facing the substrate and/or the isolation structure, a second main surface facing away from the substrate and/or the isolation structure, and a side surface connecting the first main surface and the second main surface, and the side surface of the encapsulation unit is a smooth surface. In this way, by forming the side surface of the encapsulation unit as a smooth surface, the first encapsulation layer can be more effectively protected in a preparation process of the display panel. For a structure of the display panel in this solution and a further design of the display panel, refer to related descriptions in the foregoing embodiments.

At least one embodiment of the present disclosure provides a display device, which may include the display panel in the above embodiments. For example, the display device may include a touch structure disposed on a light-emitting side of the display panel, an optical film (for example, a microlens, a polarizer), a cover plate, and the like

For example, the display device may be any product or component including a display function, such as a television, a digital camera, a mobile phone, a watch, a tablet computer, a notebook computer, a navigator, and the like.

The above are only preferred embodiments of the present specification and are not intended to limit the present specification, and any modification, equivalent replacement and the like made within the spirit and principle of the present specification shall fall within the protection scope of the present specification.

What is claimed is:

1. A display panel, comprising:
a substrate;
a plurality of light-emitting units located on the substrate;
an isolation structure located on the substrate and comprising a plurality of isolation openings respectively defining the plurality of light-emitting units; and
a first encapsulation layer covering the plurality of isolation openings and the plurality of light-emitting units, wherein a densification of the first encapsulation layer gradually decreases from one side, facing the substrate, of the first encapsulation layer to one side, away from the substrate, of the first encapsulation layer.

2. The display panel according to claim 1, wherein the first encapsulation layer comprises a plurality of encapsulation units respectively corresponding to the plurality of light-emitting units, and the first encapsulation layer is an inorganic film layer.

3. The display panel according to claim 2, wherein,
each encapsulation unit of the plurality of encapsulation units comprises a first main surface facing the substrate, a second main surface facing away from the substrate, and a first side surface connecting the first main surface and the second main surface, and
the first side surface of the encapsulation unit is a smooth surface.

4. The display panel according to claim 3, wherein, the first side surface of the encapsulation unit is a plane, and a plane where the first side surface of the encapsulation unit is located intersects and is not perpendicular to a plane where the substrate is located.

5. The display panel according to claim 1, further comprising a pixel defining layer located between the substrate and the isolation structure,
wherein the pixel defining layer defines a plurality of pixel openings, the plurality of pixel openings are arranged correspondingly to the plurality of isolation openings, an orthographic projection, on the substrate, of each pixel opening of the plurality of pixel openings is located within an orthographic projection, on the substrate, of each isolation opening of the plurality of isolation openings that corresponding to the pixel opening, and the pixel defining layer is an inorganic film layer.

6. The display panel according to claim 5, wherein a densification of the pixel defining layer gradually decreases from one side, facing the substrate, of the pixel defining layer to one side, away from the substrate, of the pixel defining layer, and
a second side surface of the pixel defining layer is a plane, and a plane where the second side surface of the pixel defining layer is located intersects and is not perpendicular to a plane where the substrate is located.

7. The display panel according to claim 1, wherein the isolation structure comprises a body portion and a roof portion located on a side, facing away from the substrate, of the body portion, an orthographic projection, on the substrate, of the body portion is located within an orthographic projection, on the substrate, of the roof portion, and
an edge of the orthographic projection, on the substrate, of the roof portion is an edge of an orthographic projection, on the substrate, of the isolation structure.

8. The display panel according to claim 7, wherein each light-emitting unit of the plurality of light-emitting unit comprises a first electrode, a light-emitting functional layer and a second electrode sequentially stacked on the substrate, and
the light-emitting functional layer and the second electrode of the each light-emitting unit are located in an isolation opening, corresponding to the each light-emitting unit, of the plurality of isolation openings, the body portion is a conductive structure, and the second electrode of the light-emitting unit is electrically connected with the body portion.

9. The display panel according to claim 8, further comprising a pixel defining layer located between the substrate and the isolation structure,
wherein the pixel defining layer defines a plurality of pixel openings, the plurality of pixel openings are arranged correspondingly to the plurality of isolation openings, the isolation structure further comprises an auxiliary body portion located between the body portion and the pixel defining layer,
an orthographic projection, on the substrate, of the auxiliary body portion is located within the orthographic projection, on the substrate, of the roof portion,
the orthographic projection, on the substrate, of the body portion is located within the orthographic projection, on the substrate, of the auxiliary body portion, and
the auxiliary body portion is a conductive structure, and the second electrode of the light-emitting unit is electrically connected with the auxiliary body portion.

10. The display panel according to claim 9, wherein a densification of the pixel defining layer gradually decreases from one side, facing the substrate, of the pixel defining layer to one side, away from the substrate, of the pixel defining layer.

11. The display panel according to claim 2, wherein, each encapsulation unit of the plurality of encapsulation units comprises a first main surface facing the substrate, a second main surface facing away from the substrate, and a side surface connecting the first main surface and the second main surface,
along a direction from the first main surface to the second main surface, the side surface comprises a plurality of sub-side surfaces connected in sequence,
an included angle between a plane and each sub-side surface of the plurality of sub-side surfaces is not greater than 45 degrees, the plane is determined by a first boundary between the side surface and the first main surface and a second boundary between the side surface and the second main surface, and
an orthographic projection, on the substrate, of the second main surface is located within an orthographic projection, on the substrate, of the first main surface.

12. The display panel according to claim 1, wherein a refractive index of the first encapsulation layer gradually decreases from the side, facing the substrate, of the first encapsulation layer to the side, away from the substrate, of the first encapsulation layer.

13. The display panel according to claim 1, wherein an oxygen content of the first encapsulation layer gradually increases from the side, facing the substrate, of the first encapsulation layer to the side, away from the substrate, of the first encapsulation layer.

14. A display panel, comprising:
a substrate;
a plurality of light-emitting units located on the substrate;
an isolation structure located on the substrate and comprising a plurality of isolation openings respectively defining the plurality of light-emitting units; and
a first encapsulation layer covering the plurality of isolation openings and the plurality of light-emitting units, and comprising a plurality of encapsulation units respectively corresponding to the plurality of light-emitting units, wherein each encapsulation unit of the plurality of encapsulation units comprises a first main surface facing the substrate, a second main surface facing away from the substrate, and a side surface connecting the first main surface and the second main surface;
wherein, along a direction from the first main surface to the second main surface, the side surface comprises a plurality of sub-side surfaces connected in sequence, an included angle between a plane and each sub-side surface of the plurality of sub-side surfaces is not greater than 45 degrees, the plane is determined by a first boundary between the side surface and the first main surface and a second boundary between the side surface and the second main surface, and an orthographic projection, on the substrate, of the second main surface is located within an orthographic projection, on the substrate, of the first main surface.

15. The display panel according to claim 14, wherein the encapsulation unit comprises a first main surface facing the substrate, a second main surface facing away from the substrate, and a side surface connecting the first main surface and the second main surface, a first side surface of the encapsulation unit is a plane, and a plane where the first side surface of the encapsulation unit is located intersects and is not perpendicular to a plane where the substrate is located.

16. The display panel according to claim 14, wherein,
a densification of the first encapsulation layer gradually decreases from one side, facing the substrate, of the first encapsulation layer to one side, away from the substrate, of the first encapsulation layer; or
the first encapsulation layer comprises at least two sub-encapsulation layers stacked with each other, and a sub-encapsulation layer of the at least two sub-encapsulation layers having a smaller distance to the substrate has a larger refractive index.

17. The display panel according to claim 16, wherein the encapsulation unit comprises a first sub-encapsulation layer, a second sub-encapsulation layer and a third sub-encapsulation layer stacked with each other, the first sub-encapsulation layer, the second sub-encapsulation layer and the third sub-encapsulation layer are sequentially arranged along a direction away from the substrate, and
the densifications or refractive indexes of the first sub-encapsulation layer, the second sub-encapsulation layer and the third sub-encapsulation layer are gradually decreases.

18. A display panel, comprising:
a substrate;
a plurality of light-emitting units located on the substrate;
an isolation structure located on the substrate and comprising a plurality of isolation openings respectively defining the plurality of light-emitting units; and
a first encapsulation layer covering the plurality of isolation openings and the plurality of light-emitting units, wherein the first encapsulation layer comprises at least two sub-encapsulation layers stacked with each other, and a sub-encapsulation layer of the at least two sub-encapsulation layers having a smaller distance to the substrate has a larger refractive index.

19. The display panel according to claim 18, wherein,
the sub-encapsulation layer of the at least two sub-encapsulation layers having a smaller distance to the substrate has a larger densification; or, the sub-encapsulation layer of the at least two sub-encapsulation layers having a smaller distance to the substrate have a smaller oxygen content.

20. The display panel according to claim 18, wherein each light-emitting unit of the plurality of light-emitting units comprises a first electrode, a light-emitting functional layer and a second electrode sequentially stacked on the substrate, the light-emitting functional layer and the second electrode of the each light-emitting unit are located in an isolation opening, corresponding to the each light-emitting unit, of the plurality of isolation openings,
the display panel further comprises a pixel defining layer located between the substrate and the isolation structure, the pixel defining layer defines a plurality of pixel openings arranged correspondingly to the plurality of isolation openings, respectively, an orthographic projection, on the substrate, of each pixel opening of the plurality of pixel openings is located within an orthographic projection, on the substrate, of the isolation opening corresponding to the pixel opening, the light-emitting functional layer and the second electrode fill the pixel opening and extend to a surface, facing away from the substrate, of the pixel defining layer, and the pixel defining layer is an inorganic film layer, and
the pixel defining layer comprises at least two sub-defining layers stacked with each other, and a sub-defining layer of the at least two sub-encapsulation layers having a smaller distance to the substrate has a larger refractive index.
